(19) United States
(12) Patent Application Publication
(10) Pub. No.: US 2005/0179092 A1
(43) Pub. Date: Aug. 18, 2005

(54) Method of fabricating high voltage device using double epitaxial growth

(75) Inventor: Kwang Young Ko, Kyunggido (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: DongbuAnam Semiconductor Inc.

(21) Appl. No.: 11/020,476

(22) Filed: Dec. 27, 2004

(30) Foreign Application Priority Data
Dec. 30, 2003 (KR) P 2003-0100993

(51) Int. Cl. H01L 29/76; H01L 29/94

(52) U.S. Cl. 257/370

(57) ABSTRACT

The present invention provides a method of fabricating a high voltage device using double expitaxial growth, by which an optimized device can be fabricated in a manner of differentiating epitaxial layers of high and low voltage devices in thickness and by which a chip size can be reduced. The present invention includes the steps of forming a first impurity-buried layer on a substrate, forming a first epitaxial layer on the substrate, forming a second impurity-buried layer on the first epitaxial layer not to be overlapped with the first impurity-buried layer, forming a second epitaxial layer on the first epitaxial layer; forming first and second wells on the first and second impurity-buried layers by ion implantation, respectively, and annealing the substrate including the first and second wells.

This application claims the benefit of the Korean Application No. P2003-0100993 filed on Dec. 30, 2003, which is hereby incorporated by reference.

### BACKGROUND OF THE INVENTION

1. Field of the Invention

The present invention relates to a method of fabricating a high voltage device, and more particularly, to a method of fabricating a high voltage device using double expitaxial growth, in which the high voltage device and a low voltage device are formed in a first epitaxial growth layer and a second epitaxial growth layer, respectively and in which ion-implanted wells are formed in the first and second epitaxial growth layers to be annealed, respectively.

2. Discussion of the Related Art

Generally, a power MOSFET has a switching speed superior to those of-other power devices

Generally, a power MOSFET device has a switching speed superior to that of other power devices and is characterized in having low ON-resistance of a device having a relatively low strength voltage below 300V, and a high-voltage lateral power MOSFET becomes popular as a high-integration power device.

There are various high-voltage power devices such as DMOSFET (double-diffused MOSFET), insulated gate bipolar transistor, EDMOSFET (extended drain MOSFET), LDMOSFET (lateral double-diffused MOSFET), etc.

Specifically, LDMOSFET is variously applicable to HSD (high side driver), LSD (low side driver), H-bridge circuit, and the like and its fabrication is facilitated. Yet, in the LDMOSFET, a doping density of a channel region is structurally uneven to bring a high threshold voltage thereof and breakdown takes place on s silicon substrate surface of a drift region in the vicinity of the channel region.

FIGS. 1A to 1D are cross-sectional diagrams for explaining a method of fabricating a MOSFET device according to a related art.

FIG. 1A shows a step of forming impurity-buried layers of high and low voltage devices, respectively.

Referring to FIG. 1A, impurity-buried layers 12 and 13 of high and low voltage devices are formed in a substrate 11, respectively. In doing so, each of the impurity-buried layers 12 and 13 is formed by ion implantation with impurity ions having a type opposite to that of the substrate 11. Namely, if a P type substrate is used, N-type impurity ions are implanted for the impurity-buried layers.

FIG. 1B shows a step of forming epitaxial layers on high and low voltage device areas, respectively.

Referring to FIG. 1B, epitaxial layers are formed on the substrate by epitaxial growth. Specifically, the epitaxial layer 14 of the high voltage device area is formed twice thicker than the epitaxial layer 15 of the low voltage device area.

FIG. 1C shows a step of forming wells in the high and low voltage device areas, respectively.

Referring to FIG. 1C, wells 16 are formed on the high and low voltage devices, respectively. In doing so, the wells 16 are formed by ion implantation.

Subsequently, annealing is carried out on the substrate so that the wells 16 can come into contact with the impurity-buried layers 12 and 13, respectively.

FIG. 1D shows a cross-sectional diagram of the high and low voltage devices after completion of the annealing.

Referring to FIG. 1D, the epitaxial layer of the high voltage device, which is thicker than that of the low voltage device, needs a prolonged annealing time to make the well contact with the impurity-buried layer below.

However, in the related art high voltage device fabricating method, the impurity ions implanted in the well 17 of the low voltage device diffuses in both a vertical direction to contact with the impurity-buried layer and a horizontal direction due to the prolonged annealing time, thereby increasing a size of the low voltage device.

### SUMMARY OF THE INVENTION

Accordingly, the present invention is directed to a method of fabricating a high voltage device using double expitaxial growth that substantially obviates one or more problems due to limitations and disadvantages of the related art.

An object of the present invention is to provide a method of fabricating a high voltage device using double expitaxial growth, by which an optimized device can be fabricated in a manner of differentiating epitaxial layers of high and low voltage devices in thickness and by which a chip size can be reduced.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a method of fabricating a high voltage device using double epitaxial growth according to the present invention includes the steps of forming a first impurity-buried layer on a substrate, forming a first epitaxial layer on the substrate, forming a second impurity-buried layer on the first epitaxial layer not to be overlapped with the first impurity-buried layer, forming a second epitaxial layer on the first epitaxial layer; forming first and second wells on the first and second impurity-buried layers by ion implantation, respectively, and annealing the substrate including the first and second wells.

Preferably, the first impurity-buried layer is to form a high voltage device area.

Preferably, the second impurity-buried layer is to form a low voltage device area.

Preferably, a total thickness of the first and second epitaxial layers corresponds to a thickness of the first well.

More preferably, the first well is to form a high voltage device area.

Preferably, the first and second epitaxial layers are formed equal to each other in thickness.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIGS. 1A to 1D are cross-sectional diagrams for explaining a method of fabricating a high-voltage device according to a related art; and

FIGS. 2A to 2E are cross-sectional diagrams for explaining a method of fabricating a high-voltage device according to the present invention.

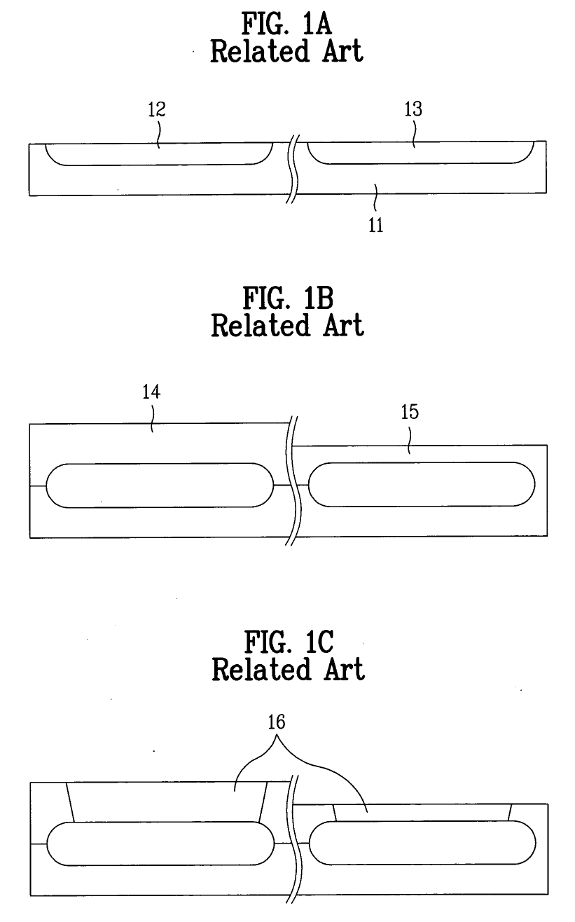

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

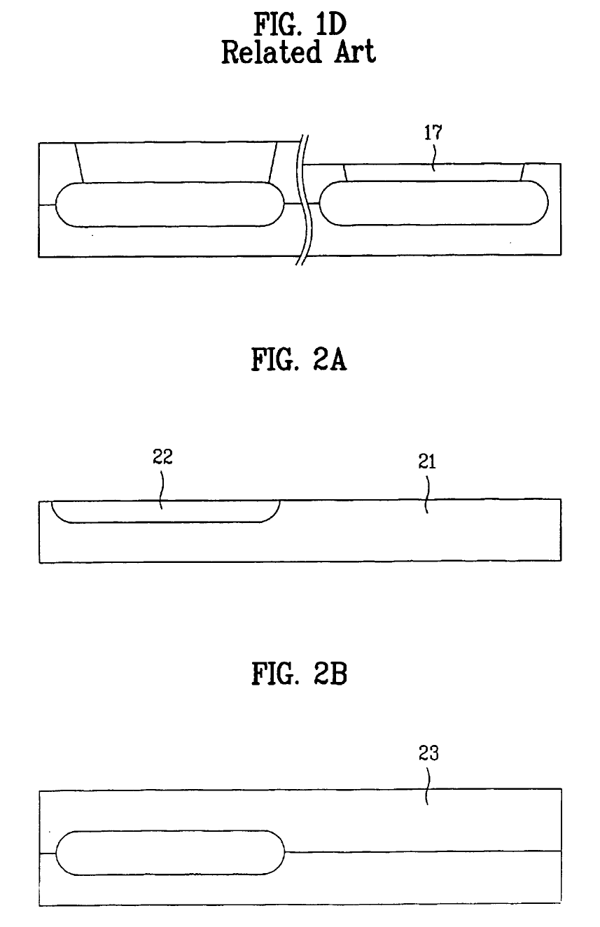

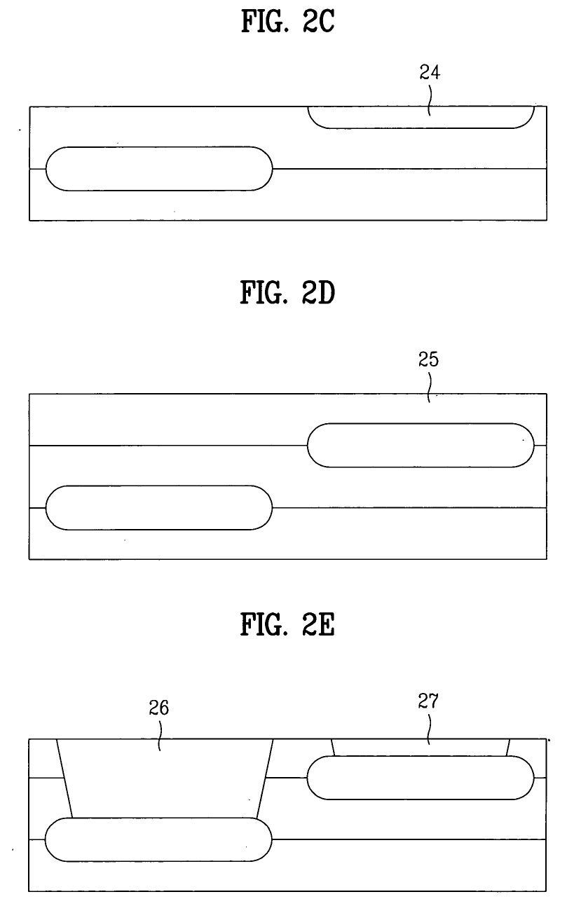

FIGS. 2A to 2E are cross-sectional diagrams for explaining a method of fabricating a high-voltage device according to the present invention.

FIG. 2A shows a step of forming a first impurity-buried layer on a substrate having a prescribed device formed therein.

Referring to FIG. 2A, a first impurity-buried layer 22 is formed on a prescribed area of a substrate 21 having a prescribed device formed therein to form a high voltage device area. In doing so, the first impurity-buried layer 22 is formed by ion implantation with impurity ions having a type opposite to that of the substrate 21.

FIG. 2B shows a step of forming a first epitaxial layer on the substrate.

Referring to FIG. 2B, a first epitaxial layer 23 is formed on the substrate 21 including the first impurity-buried layer 22. In doing so, a thickness of the first epitaxial layer 23 is set to a half thickness of a total epitaxial layer.

FIG. 2C shows a step of forming a second impurity-buried layer in the first epitaxial layer.

Referring to FIG. 2C, a second impurity-buried layer 24 is formed on the first epitaxial layer 23 by ion implantation. In doing so, the second impurity-buried layer 24 is formed smaller than the first impurity-buried layer. This is because the second impurity-buried layer 24 operates at a voltage lower than that of the first impurity-buried layer.

FIG. 2D shows a step of forming a second epitaxial layer on the first epitaxial layer.

Referring to FIG. 2D, a second epitaxial layer is formed on the first epitaxial layer having the second impurity-buried layer formed thereon. In doing so, a thickness of the second epitaxial layer 25 is formed similar to that of the first epitaxial layer so that a total thickness of the first and second epitaxial layers can be equal to that of the related art epitaxial layer. And, the total thickness of the first and second epitaxial layers becomes a total thickness of the epitaxial layer of the high voltage device area and a thickness of a well of a high voltage device that will be formed later.

FIG. 2E shows a step of forming wells on the substrate by ion implantation and annealing the wells.

Referring to FIG. 2E, impurities for forming wells are implanted into the first and second epitaxial layers on the first and second impurity-buried layers as the high and low voltage device areas, respectively.

Subsequently, the substrate is annealed to form a well 26 of the high voltage device and a well 27 of a low voltage device. In doing so, since the thickness of the high voltage device area is smaller than that of the low voltage device area, a horizontal diffusing area of the impurities implanted for well formation is reduced. Hence, the low voltage device area of the present invention is smaller than that of the related art.

Accordingly, by the high voltage device fabricating method according to the present invention, an optimized device can be fabricated in a manner of differentiating epitaxial layers of high and low voltage devices in thickness and a chip size can be reduced.

It will be apparent to those skilled in the art that various modifications and variations can be made in the present invention. Thus, it is intended that the present invention covers the modifications and variations of this invention provided they come within the scope of the appended claims and their equivalents.

1. A method of fabricating a high voltage device using double epitaxial growth, comprising the steps of:
forming a first impurity-buried layer on a substrate;
forming a first epitaxial layer on the substrate;
forming a second impurity-buried layer on the first epitaxial layer not to be overlapped with the first impurity-buried layer;
forming a second epitaxial layer on the first epitaxial layer; forming first and second wells on the first and second impurity-buried layers by ion implantation, respectively; and
annealing the substrate including the first and second wells.

2. The method of claim 1, wherein the first impurity-buried layer is to form a high voltage device area.

3. The method of claim 1, wherein the second impurity-buried layer is to form a low voltage device area.

4. The method of claim 1, wherein a total thickness of the first and second epitaxial layers corresponds to a thickness of the first well.

5. The method of claim 4, wherein the first well is to form a high voltage device area.

6. The method of claim 1, wherein the first and second epitaxial layers are formed equal to each other in thickness.
